(19) United States
(12) Patent Application Publication
(10) Pub. No.: US 2017/0062289 A1
(43) Pub. Date: Mar. 2, 2017

(54) At least partially balancing out thickness variations of a substrate

(71) Applicant: Infineon Technologies AG, Neubiberg (DE)

(72) Inventors: Carsten VON KOBLINSKI, Villach (AT); Manfred ENGELHARDT, Villach-Landskron (AT)

(21) Appl. No.: 15/247,400

(22) Filed: Aug. 25, 2016

(30) Foreign Application Priority Data
Aug. 28, 2015 (DE) 10 2015 114 307.0

(51) Int. Cl. H01L 21/66; H01L 21/304; H01J 37/32; H01L 21/308

(52) U.S. Cl. CPC H01L 22/26; H01L 21/3081; H01L 21/304; H01J 37/32651; H01J 37/32935; H01J 2237/24578; H01J 2237/334; H01J 2237/026

(57) ABSTRACT

A method of thinning a substrate, the method comprising subjecting the substrate to a thinning process, determining information indicative of a surface topography of the thinned substrate, and selectively removing material from at least one surface portion of the thinned substrate based on the determined information to thereby at least partially balance out thickness variations.

### BACKGROUND

Field

The present invention relates to a method of thinning a substrate, a method of at least partially balancing out a surface topography of a substrate, an apparatus for at least partially balancing out a surface topography of a substrate, a structure, and a lithography device.

Description of the Related Art

In the field of manufacturing processes of semiconductor elements the semiconductor elements are often processed on a wafer scale. With the proceeding of the technology often so called thin film wafer are used even in the field of power modules, i.e. modules comprising semiconductor elements or chips designed for withstanding high voltages or currents. These power modules are used in rectifiers or inverters in the automotive sector, for example. For reducing the thickness of the chips, e.g. transistors or diodes, the bulk of the wafer itself is often used for providing or defining the inverse or block voltage. As a general rule each 1 micrometer of thickness corresponds to 10 V inverse voltage.

However, due to the fact that the bulk or thickness of the wafer itself and not of an (epitaxial) deposited layer defines the block voltage, variations in the thickness of the wafer directly correspond to a variation of the blocking voltages and thus directly effects the performance of the electronic element or component. Therefore, the total thickness variation of the bulk wafer or any other kind of substrate should be as low as possible. Therefore a plurality of complex measures are performed in the prior art to reduce the total thickness variation.

### SUMMARY

There may be a need to provide thin substrates with high thickness accuracy and without the risk of quality deteriorations.

According to an exemplary embodiment, a method of thinning a substrate is provided, wherein the method comprises subjecting the substrate to a thinning process, determining information indicative of a surface topography of the thinned substrate, and selectively removing material from at least one surface portion of the thinned substrate based on the determined information to thereby at least partially balance out thickness variations.

According to another exemplary embodiment, a method of at least partially balancing out a surface topography of a substrate is provided, wherein the method comprises determining information indicative of the surface topography of the substrate, adjusting a mask in accordance with the determined information, and selectively removing material from at least one surface portion of the substrate using the adjusted mask to thereby at least partially balance out thickness variations.

According to yet another exemplary embodiment, an apparatus for at least partially balancing out a surface topography of a substrate is provided, wherein the apparatus comprises a determining unit configured for determining information indicative of the surface topography of the substrate, a mask being adjustable in accordance with the determined information, and a material removal unit configured for selectively removing material from at least one surface portion of the substrate using the adjusted mask to thereby at least partially balance out thickness variations.

According to still another exemplary embodiment, a structure is provided which comprises a semiconductor substrate having a first main surface with a surface topography and having a second main surface opposing the first main surface and having at least one circuit element integrated therein, and a patterned layer covering the first main surface excluding at least one surface portion in which the surface topography exceeds a predefined threshold value or has a local or global maximum.

According to yet another exemplary embodiment, a lithography device for processing a substrate is provided, wherein the lithography device comprises a mask configured for being controllable to provide a variable spatial transmissivity pattern for a lithography beam, and a control unit (such as a processor) configured for controlling the mask for adjusting the (in particular re-adjustable) spatial transmissivity pattern of the mask in accordance with at least one property of the substrate (in particular a surface topography of the substrate) to be processed.

An exemplary embodiment has the advantage that thinning of a substrate is carried out based on previously determined information indicative of a topography of the substrate to be thinned equally. Thus, the total thickness variation of the substrate may be reduced by selectively removing more material in one or more surface portions of the substrate in which the determined information indicates that this at least one surface portion of the substrate has a relatively pronounced topography.

Exemplary embodiments of the invention adjust transmissivity of different spatial portions of a mask used in terms of planarizing a substrate by fine thinning or post thinning in accordance with previously determined information indicative of surface topography of the substrate. In accordance with this mask having a settable spatial distribution of the transmissivity, a spatial distribution of material of the substrate removed from corresponding surface portions may be selected to thereby reduce the total thickness variation.

According to an exemplary embodiment, a mask—in particular of the above-mentioned type—may be used for patterning a previously continuous layer on the substrate with the surface topography for selectively exposing one or more regions of the substrate in which the local thickness of the substrate is high. In a subsequent selective material removal procedure, material may be selectively removed exclusively or predominantly from the exposed at least one portion of the substrate, i.e. where the patterned layer is not present. This allows to efficiently reduce the total thickness variation.

In particular in order to cope with different substrates having different surface topography and therefore different surface thickness variations, one and the same mask may be specifically adjusted (and preferably multiple times re-adjusted) for treating the different substrates subsequently in correspondence with previously determined surface topography information characterizing the respective substrate. Thus, the above described procedure of reducing the total thickness variation can be flexibly applied to different substrates with different properties using one and the same apparatus.

### DESCRIPTION OF FURTHER EXEMPLARY EMBODIMENTS

In the following, further exemplary embodiments of the methods, the apparatus, the structure, and the lithography device will be explained.

By exemplary embodiments of the invention, it may be possible to reduce the total thickness variation of a substrate such as a semiconductor wafer to less than 10 μm, in particular to less than 5 μm, for instance in a range between 1 μm and 10 μm.

In the context of the present application, the term “surface topography” may particularly denote a height profile being indicative of a spatial height distribution over a two-dimensional surface area of the substrate to be planarized.

In an embodiment, the method comprises adjusting an adaptive variable mask, in particular an adaptive variable lithography mask, in accordance with the determined information, and carrying out the selective removal of the material using the adjusted mask. When information about the two-dimensional height profile over the surface area of the substrate to the processed has been obtained, this information may be transformed into a transmissivity pattern of the two-dimensional area of the mask. When using the mask for processing the surface of the substrate, the transmissivity pattern of the mask translates into a corresponding patterning of the substrate. In a corresponding lithography procedure, the information about the height profile may therefore be used for leveling the substrate.

In an embodiment, the thinning process is selected from a group consisting of grinding (or any other mechanical material removal procedure) and etching (or any other chemical material removal procedure).

In an embodiment, the determining is selected from a group consisting of capacitively determining, mechanically determining and optically determining. Hence, the change of a capacity value when a probe scans the surface of the substrate, the change of a mechanical displacement of a probe scanning the surface of the substrate and/or the change of a reflection and/or transmission property of electromagnetic radiation being directed onto the surface of the substrate may be used for determining the information about the surface profile.

In an embodiment, the removing is selected from a group consisting of etching (in particular plasma etching) and grinding. Any desired selective material removal procedure can be carried out which allows to remove different amounts of material from different surface portions of the substrate having the surface profile and being covered or not covered by a layer.

In an embodiment, the substrate is a semiconductor substrate (such as a semiconductor wafer or a semiconductor chip) having a first main surface with the surface topography and having a second main surface opposing the first main surface and having at least one circuit element (in particular monolithically) integrated therein. In other words, the first main surface may be the surface of the semiconductor substrate at which a thinning procedure, resulting in the surface topography, has been carried out previously. Correspondingly, the second main surface of the semiconductor substrate may be the active surface of the semiconductor substrate in which integrated circuit elements such as transistors, diodes, capacitances, resistors, etc. have been integrated to provide a desired electronic functionality. In particular, such one or more circuit elements may involve a vertical current flow through the substrate. This renders it particularly advantageous to have a substantially homogeneous thickness of the substrate so as to ensure an appropriate reproducibility of the functioning of the semiconductor substrate.

In an embodiment of the method, the substrate is mounted on a carrier prior to the thinning process. Correspondingly, the structure may comprise a carrier on which the semiconductor substrate is mounted, wherein the second main surface may be in contact with the carrier. Such a temporary carrier (which is to be removed from the substrate after the thickness equilibration procedure) or permanent carrier (which remains connected to the substrate and therefore remains part of the final product after the thickness equilibration procedure) on which the substrate can be mounted prior to the thickness equilibration procedure may improve and simplify handling of the thin substrate.

In an embodiment, the method comprises forming, in particular after the determining, a patterned layer on the substrate which covers the first main surface excluding at least one surface portion in which the surface topography exceeds a predefined threshold value or has a maximum. Furthermore, it is possible to carry out the selective removal of material of the substrate while the patterned layer covers part of the substrate. After the selective removal of material of the substrate, the patterned layer may be removed from the substrate. According to such a preferred embodiment, a conformal (i.e. with homogeneous thickness) layer may be deposited, attached or applied with any other procedure on the substrate and may be subsequently partially removed by a patterning procedure selectively from those surface portions of the substrate having locally a very high thickness (for instance above a predefined threshold value or representing a local or even global maximum thickness of the substrate). Thus, projections of the substrate may be freed from the patterned layer, whereas indentations of the substrate may remain covered with the layer. When this procedure is followed by a selective etching procedure which is configured so as to remove exposed material of the substrate only while being incapable of removing material of the patterned layer (or at least removing the latter material with a lower etching rate), execution of the selective etching procedure results in a balancing of thickness variations of the substrate by removing material from the protrusions while preventing (or at least inhibiting) removing material of the indentations being covered by the substantially non-etchable patterned layer.

In an embodiment, the method comprises forming a layer, in particular a conformal layer, on the substrate which covers the first main surface, and gradually reducing a thickness of the layer up to a reduced thickness which gradually differs for different surface portions in accordance with a different surface topography of the substrate in the different surface portions. Gradually reducing a thickness of the layer, for instance embodied as a photoresist, can be accomplished by a time delayed individual switching of the various sections of a mask with a controllable spatial distribution of transmissivity. The longer a portion of a layer is exposed to radiation, the more can the layer be locally thinned, and vice versa. According to such an embodiment, the patterning of the conformal layer is not only carried out “digitally” (i.e. forming one or more first surface portions without the layer and forming one or more second surface portions being covered with the layer in full thickness), but in contrast to this a predefined thickness profile of the previously homogeneously thick layer is adapted in accordance with the surface topography of the substrate. More specifically, the thickness profile of the gradually thinned layer may be adjusted inverse to the thickness profile (or the surface topography) of the substrate under the layer (compare FIG. 13). This has the advantage that, in a subsequent selective etching process, regions of the substrate being covered with the layer with full thickness may be protected strongly or fully from material removal of the substrate, regions of the substrate being uncovered with the layer experience a high thickness reduction of the substrate, and regions of the substrate being covered with a reduced layer thickness may experience a smaller reduction of the substrate thickness in accordance with the remaining local thickness of the layer. Such a gradual thinning of the layer may be accomplished by using a lithography mask by which, for each individual surface region of the originally conformal layer, any desired individual exposure time of electromagnetic radiation can be adjusted. Hence, gradually reducing the thickness of the layer for the different surface portions may be advantageously accomplished by individually adjusting a lithographic exposure time interval for each respective surface portion and therefore for each corresponding pixel of the mask individually. This, in turn, can be done with a mask being configured for being controllable to provide a variable spatial transmissivity pattern for a lithography beam such as an electromagnetic radiation beam. As a consequence, a first section of the layer may be completely removed, a second section of the layer may be completely remained, and a third section of the layer may be thinned without exposing the substrate portion below.

In an embodiment, the method comprises, prior to be determining, subjecting the substrate to a thinning process resulting in the surface topography. Such a thinning may be accomplished mechanically (for instance by grinding or polishing) and/or chemically (for instance by etching) and/or by an electromagnetic radiation treatment (such as laser ablation).

In an embodiment, the mask is an electrically configurable shadow mask. That means that individual portions (such as pixels) of the mask may be controlled by an electric signal so as to assume a controllable transmissivity value. In one embodiment, each individual portion may be controlled to be either transparent or opaque so that each individual portion may even allow a lithography beam to fully pass or not pass this individual portion of the mask to thereby impinge or not impinge on a corresponding surface portion of the substrate (or a layer thereon). Alternatively, any desired transmissivity value (for instance between “1”, i.e. completely transparent, and “0”, i.e. completely opaque) may be adjusted individually for each individual portion of the mask (for instance 0.7). Such an electrically configurable shadow mask may be implemented by a liquid crystal arrangement between opposing electrodes (preferably made of electrically conductive optically transparent material, such as ITO, indium tin oxide). Applying a certain electric control signal between two electrodes in a certain portion of such an electrically controllable shadow mask allows to generate an electric field forcing the locally positioned liquid crystal particles to assume a certain orientation, which results, in turn, in a corresponding value of the local transmissivity.

In an embodiment, the mask comprises a two-dimensional array of mask pixels each having an individually adjustable transmissivity. For instance, each individual pixel of a pixel array, in particular a two-dimensional array with rows and columns, of the mask may be controlled individually in terms of transmissivity.

In an embodiment, the patterned layer is made of a material having a significantly lower removal rate than a material of the substrate which is exposed in the at least one surface portion. For instance, the material of the layer may be a photoresist, whereas the material of the substrate may be silicon. This allows to carry out a selective etching of material of the substrate versus material of the patterned layer which translates into a reduced value of the total thickness variation of the substrate.

In an embodiment, a thickness of the substrate is lower than 100 μm, in particular is lower than 70 μm. Particularly with such very thin substrates, local thickness variations may have a significant impact on the electric performance of an electronic chip constituting or forming part of the substrate. This particularly holds when integrated circuit elements of the substrate rely on a vertical current flow during operation. Thus, for such kind of substrates, a sufficiently small value of the total thickness variation is of utmost advantage.

In an embodiment, the mask is configured for being controllable to provide the variable spatial transmissivity pattern based on at least one of the group consisting of an electric control of liquid crystal material, and a control of a plurality of individually controllable mechanical flaps. As an alternative to the above described configuration with a spatial distribution of electrically switchable liquid crystal material, it is also possible to embody the adjustable controllable mask as an array of (in particular opaque) flaps which may be pivoted so as to either allow or block (both fully or partially) transmission of electromagnetic radiation through the flap.

In an embodiment, the at least one circuit element is configured for providing a power semiconductor application. For instance, the substrate or part thereof (for instance an electronic chip or a semiconductor chip singularized from the substrate) may be used for power applications for instance in the automotive field and may for instance have at least one integrated insulated-gate bipolar transistor (IGBT) and/or at least one integrated diode.

In an embodiment, the at least one circuit element is configured for providing a vertical current flow in thickness direction of the substrate during operation. The small total thickness variation obtainable by exemplary embodiments of the invention renders the architecture particularly appropriate for high power applications in which a vertical current flow is desired. For such kind of devices, a rule of thumb is that one micrometer of thickness corresponds to 10 V blocking voltage. Thus, even very small thickness variations may have an impact on the electrical performance and reliability of the device. Also the reproducibility of the electrical performance of different devices requires a small total thickness variation.

In an embodiment, the substrate comprises one or more semiconductor chips, in particular one or more semiconductor power chips. For example, such a semiconductor power chip may be used for automotive applications. A semiconductor power chip may comprise one or more field effect transistors, diodes, inverter circuits, half-bridges, etc.

In an embodiment, the substrate is a semiconductor wafer. As substrate or wafer forming the basis of electronic chips, a silicon substrate may be used. Alternatively, a silicon oxide or another insulator substrate may be provided. It is also possible to implement a germanium substrate or a III-V-semiconductor material. For instance, exemplary embodiments may be implemented in GaN or SiC technology.

Exemplary embodiments may make use of standard semiconductor processing technologies such as appropriate etching technologies (including isotropic and anisotropic etching technologies, particularly plasma etching, dry etching, wet etching), patterning technologies (which may involve lithographic masks), deposition technologies (such as chemical vapor deposition (CVD), plasma enhanced chemical vapor deposition (PECVD), atomic layer deposition (ALD), sputtering, etc.).

The above and other objects, features and advantages of exemplary embodiments will become apparent from the following description and the appended claims, taken in conjunction with the accompanying drawings, in which like parts or elements are denoted by like reference numbers.

### BRIEF DESCRIPTION OF THE DRAWINGS

The accompanying drawings are included to provide a further understanding of exemplary embodiments and constitute a part of the specification.

In the drawings:

FIG. 1 to FIG. 5, FIG. 7 to FIG. 8b show cross-sectional views and FIG. 6 shows a plan view of structures obtained during carrying out a method of processing a substrate according to an exemplary embodiment.

FIG. 9 shows two plan views of an electrically adjustable shadow mask used in a method and an apparatus according to an exemplary embodiment.

FIG. 10 shows thickness topologies of various substrates and, for one of the substrates, correspondingly adjusted masks with different granularities according to an exemplary embodiment.

FIG. 11 illustrates an apparatus for at least partially balancing out a surface topography of a substrate according to an exemplary embodiment.

FIG. 12 illustrates a lithography device according to an exemplary embodiment.

FIG. 13 illustrates structures obtained during a process of gradually reducing thickness of a layer deposited on a substrate for balancing out a surface topography in a subsequent selective material removal procedure.

### DETAILED DESCRIPTION OF EXEMPLARY EMBODIMENTS

The illustration in the drawing is schematically and not to scale.

Before exemplary embodiments will be described in more detail referring to the figures, some general considerations will be summarized based on which exemplary embodiments have been developed.

According to an exemplary embodiment of the invention, a method of reducing the local total thickness variation of thinned silicon wafers is provided. According to an exemplary embodiment, this can be accomplished by a spatially dependent mapping of a thickness variation of the substrate (such as the wafer) using lithographic methods. In this context, a set of data resulting from a thickness measurement over a surface of the substrate may be linked with an adaptive variable lithography mask.

After thinning (for instance using methods such as grinding or etching) a substrate (for instance a semiconductor wafer), which may or may not be mounted with its active surface on a carrier, a measurement method may be carried out which may determine the substrate thickness at a defined number of positions of the substrate or by continuously scanning the entire surface area of the substrate. Such a measurement can be executed by capacitive, mechanical or optical method, or a combination of such methods. The number of measurement points may be in a range between one measurement point and several 100,000 measurement points. In this context, it is possible to generate a topography map of the thickness distribution. On this basis, a graphic image or a matrix of the thickness distribution of the substrate (for instance the silicon thickness distribution of a wafer) can be generated. This signature of the thickness distribution is unique for each substrate and can be used for a subsequent individualized and therefore highly accurate planarization.

After thinning the substrate, such a graphic pattern is generated by executing and evaluating the described measurement. For selectively opening and subsequently processing of topographic unevenness (in particular one or more regions at and/or around a local or global maximum), a layer (such as a photoresist layer, which may be a positive photoresist or a negative photoresist) with an appropriate thickness can be applied to the backside (i.e. the main surface being free of integrated circuit elements) of the substrate. This layer may then be exposed to electromagnetic radiation using a lithographic equipment, wherein an implemented mask can be (re-)adjusted differently and individually for each substrate exposure. Preferably, such a mask may be an electrically configurable shadow mask being configured for enabling exposure of certain regions of the substrate in accordance with the topography data set obtained in terms of the spatially dependent thickness measurement of the substrate. Accordingly, the electrically configurable shadow mask can shield other regions of the substrate from the exposure with the electromagnetic radiation. The photoresist may be developed accordingly. By such a procedure, regions with a higher topography are exposed, whereas regions with a lower topography remain covered partially or fully with the layer. The granularity (and corresponding pixel size) of the exposed and non-exposed surface areas of the substrate may be freely selected. A higher granularity results in a higher precision. A lower granularity results in a lower effort for reducing the total thickness variation.

The electrically configurable shadow mask can be adapted to the regions to be exposed depending on the topography data. This can be done directly prior to the exposure of the backside of the substrate (i.e. the main surface of the substrate being free of integrated circuit elements). The result of this exposure is, after a subsequent lithographic processing (developing, curing, etc.), a wafer having portions with a high topography being free of the layer and being therefore freely accessible for subsequent selective fine thinning procedure (for instance by etching). In contrast to this, portions with a lower topography being still covered (fully or partially) with the layer are either not accessible (when being fully covered with the layer) or being only accessible to a lower extent (when being covered only partially with a thin layer) for a subsequent fine thinning procedure. Such a fine thinning procedure can be carried out for example using a plasma having a high selectivity with regard to the material of the patterned layer on the surface portion(s) of the substrate which shall not be fine thinned for planarization. Fine thinning may also be accomplished by wet chemical etching (for instance an alkaline etching using TMAH (Tetramethylammonium hydroxide), or an acidic etching). Selectivity of the used media for back thinning material of the substrate versus material of the patterned layer is technologically highly advantageous. The amount of partial back thinning for finally reducing the total thickness variation of the substrate can also be defined in accordance with the data that is indicative of the measured thickness distribution over the main surface of the substrate to be planarized.

After the described fine planarization of the exposed regions or areas of the substrate, the remaining portions of the patterned layer may be removed from the substrate (for instance by wet chemical cleaning or plasma asking). As a result, the fine planarized backside of the substrate is exposed for further processing. Additionally or alternatively, the described procedure of reducing total thickness variation can repeated one or several times, if desired.

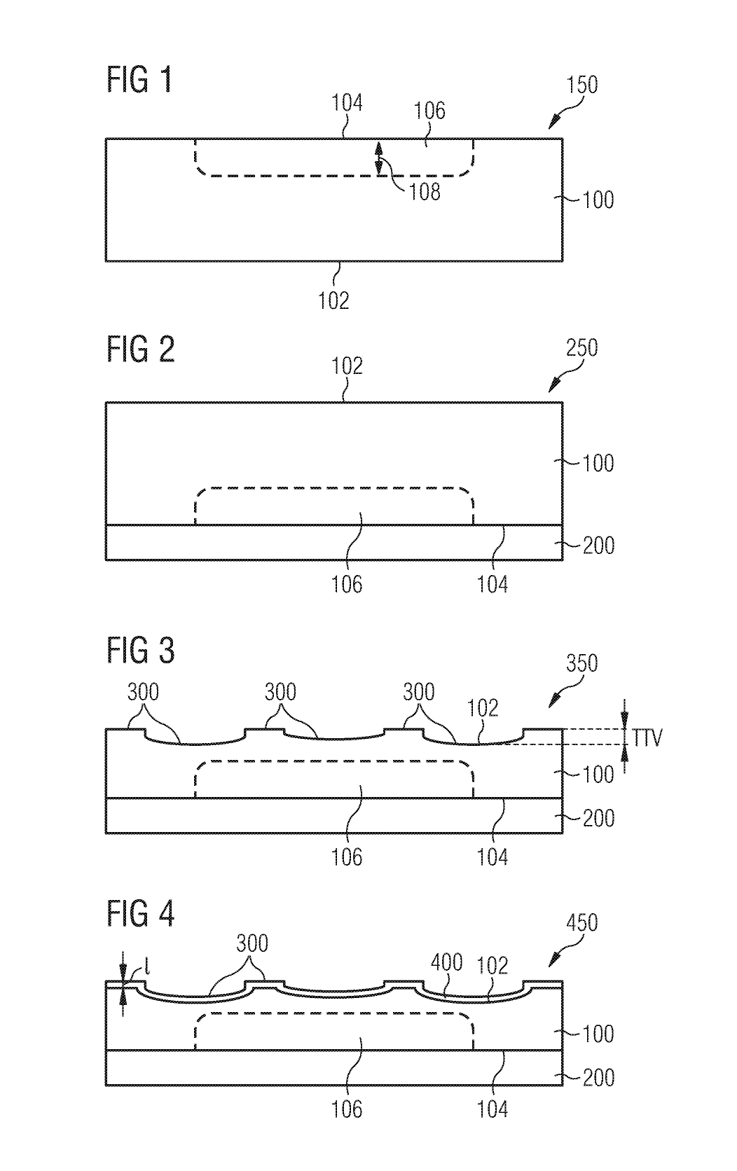

FIG. 1 shows a cross-sectional view of a structure 150 obtained during carrying out a method of thinning a substrate 100 according to an exemplary embodiment.

The substrate 100 shown in FIG. 1 is a semiconductor wafer having a first main surface 102 and having a second main surface 104 opposing the first main surface 102. One or more monolithically integrated circuit elements 106, which are not shown in detail in FIG. 1, are integrated in a surface portion of the substrate 100 adjacent to the second main surface 104. Such integrated circuit elements 106 may be transistors, diodes, capacitances, etc. The monolithically integrated circuit elements 106 may be configured for providing a power semiconductor application which may involve, during operation, a vertical current flow in thickness direction of the substrate 100 during operation (as indicated schematically in FIG. 1 by arrow 108).

Hence, FIG. 1 shows a non-thinned substrate 100 embodied as a semiconductor wafer before thinning. The second main surface 104 can also be denoted as front side, whereas the first main surface 102 can also be denoted as backside. The front side of the substrate 100 is already patterned and readily processed.

In order to obtain structure 250 shown in FIG. 2, the substrate 100 is optionally mounted reversibly on a temporary, or irreversibly on a permanent, carrier 200 prior to the thinning process. The attachment to the carrier 200 simplifies handling of the substrate 100, in particular during and after thinning (see FIG. 3). It should be noted that the substrate 100 has been pivoted upside down by 180° in order to obtain structure 250 based on structure 150. After the attachment, the second main surface 104 is in direct contact with a carrier system including the carrier 200 (and optionally at least one further element such as an adhesive material, glue, etc.).

In order to obtain structure 350 shown in FIG. 3, the exposed first main surface 102 of the substrate 100 is thinned by a thinning process, for instance by grinding and/or etching. This results in a pronounced surface topography 300 of the processed first main surface 102 having consequently a significant total thickness variation, indicated schematically in FIG. 3 as TTV. Thus, the structure 350 shows the semiconductor wafer thinned with thinning equipment. After the thinning, an average thickness of the substrate 100 may be for instance 80 μm. A resulting unevenness of the thinned first main surface 102 is indicated as surface topography 300. The total thickness variation (TTV) is the vertical distance between the portion of the substrate 100 with the highest thickness and the portion of the substrate 100 with the lowest thickness.

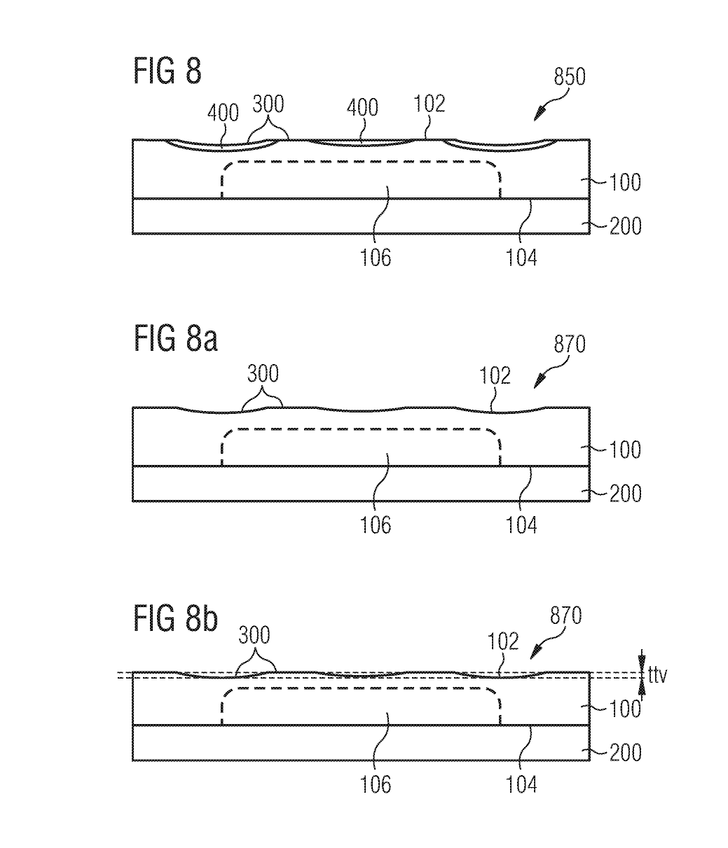

In order to reduce the TTV according to an exemplary embodiment of the invention, a measurement is carried out for determining information quantifying the amount and spatial distribution of the surface topography 300 of the thinned substrate 100. This information may be determined by a capacitive measurement, a mechanical measurement, an optical measurement, etc. The measurement may be performed at one or multiple defined surface points of the substrate 100. Alternatively, the measurement may scan the entire two-dimensional area of the first main surface 102. The result of such a measurement and determination is shown as reference numeral 1000 in FIG. 10 indicating, for five different substrates 100, the respective substrate-specific individual thickness distribution over the first main surface 102 of the respective substrate 100. As will be described in the following in further detail, the measured information is used for partially balancing out the surface topography 300 of each respective substrate 100 individually.

In order to obtain structure 450 shown in FIG. 4, a conformal layer 400 is deposited on the first main surface 102 of the substrate 100 having the surface topography 300. Consequently, the conformally deposited layer 400 homogeneously covers the first main surface 102 with a constant thickness, l. In the shown embodiment, layer 400 is made of a photosensitive varnish such as a polymeric photoresist. The material of the layer 400 is selected so that the material of the substrate 100 beneath is selectively etchable with respect to the material of the layer 400.

In order to obtain structure 550 shown in FIG. 5, an adaptive variable lithography mask 500 is placed between an electromagnetic radiation source 502, configured for emitting electromagnetic radiation 504, and the structure 450. As can be taken from FIG. 5, the mask 500 comprises opaque sections which do not allow the electromagnetic radiation 504 to propagate up to the layer 400, and comprises transparent sections which do allow the electromagnetic radiation 504 to propagate up to the layer 400. Thus, exposure and non-exposure of the different surface portions of the structure 450 to the electromagnetic radiation 504 is defined by the mask 500. Highly advantageously, the adaptive variable lithography mask 500 is configured for being controllable to set any desired two-dimensional transmissivity pattern in accordance with the determined information of the surface topography 300 of substrate 100 which is presently processed (more precisely previously thinned and subsequently planarized). Consequently, since the spatial transmissivity distribution of the mask 500 is adjusted in correspondence with the previously determined information indicative of the surface topography 300 of the substrate 100, only those surface areas of the first main surface 102 of the substrate 100 are exposed with the electromagnetic radiation 504 which have a thickness higher than a predetermined threshold value.

Structure 450 is hence made subject of a lithographic exposure in FIG. 5. This exposure is however limited to partial regions of high topography, i.e. regions of the substrate 100 being responsible for the previously high value of the TTV. This selective exposure can be accomplished by a combination of the electrically controllable shadow mask 500 and a corresponding data set indicative of the result of the thickness measurement of the substrate 100 which is used for adjusting the mask 500.

FIG. 6 shows a plan view of a structure 700 obtained during carrying out the method of thinning substrate 100 according to an exemplary embodiment. After the lithographic development, certain portions of the substrate 100 are exposed in accordance with the surface topography 300. Selectively the exposed portions are made subject to a subsequent back thinning procedure. FIG. 7 shows a corresponding cross-sectional view of a corresponding structure 700.

Based on the structure 550 exposed in accordance with mask 500 as shown in FIG. 5, the layer 400 is patterned by removing certain portions of the layer 400, however excluding surface portions of the substrate 100 from the removal in which the surface topography 300 does not exceed the predefined threshold value or is not located sufficiently close to a maximum of thickness. Thus, in order to obtain structure 700 based on structure 450, the layer 400 is patterned and removes material of the layer 400 only from surface portions in which the surface topography 300 exceeds the predefined threshold value or has a maximum of thickness.

Hence, the obtained structure 700 comprises the thinned semiconductor substrate 100 with the surface topography 300 on the thinned first main surface 102 opposing the second main surface 104 with the monolithically integrated circuit elements 106. The structure 700 further comprises the patterned layer 400 covering the first main surface 102 excluding the surface portions of pronounced thickness or elevation compared to a minimum thickness or an average thickness.

FIG. 7a, indicates with reference numeral Δ material which will be subsequently removed by a planarizing back etching procedure. Since the patterned layer 400 is made of a material having a significantly lower removal rate than a material of the substrate 100 which is exposed in certain surface portions, a following selective etching procedure will remove substantially only material from the exposed surface portions of the first main surface 102 of the substrate 100 rather than material of the layer 400.

In order to obtain structure 850 shown in FIG. 8, material from the exposed surface portions of the thinned substrate 100 are selectively removed in accordance with the determined information, which has been translated into the exposure pattern of mask 500 to thereby balance out thickness variations. This removing procedure may be for instance embodied as plasma etching. Thus, the selective removal of the material can be carried out in accordance with the adjusted mask 500. Furthermore, the selective removal of material of the substrate 100 can be carried out while the patterned layer 400 still covers part of the substrate 100, thereby reducing TTV. In other words, the planarization thinning is limited to those surface portion of the substrate 100 at which the layer 400 has openings, i.e. in varnish opening regions. A result of this procedure is a total thickness variation which is significantly lower than before the partial back etching procedure (see FIG. 8a, FIG. 8b).

In order to obtain structure 870 shown in FIG. 8a, any remaining material of the patterned layer 400 is removed (for instance stripped) from the substrate 100 after the selective removal of material of the substrate 100. The structure 870 is shown again in FIG. 8b, where also the reduced total thickness variation (here denoted as ttv) after the processing according to the described exemplary embodiment of the invention can be seen (ttv<TTV).

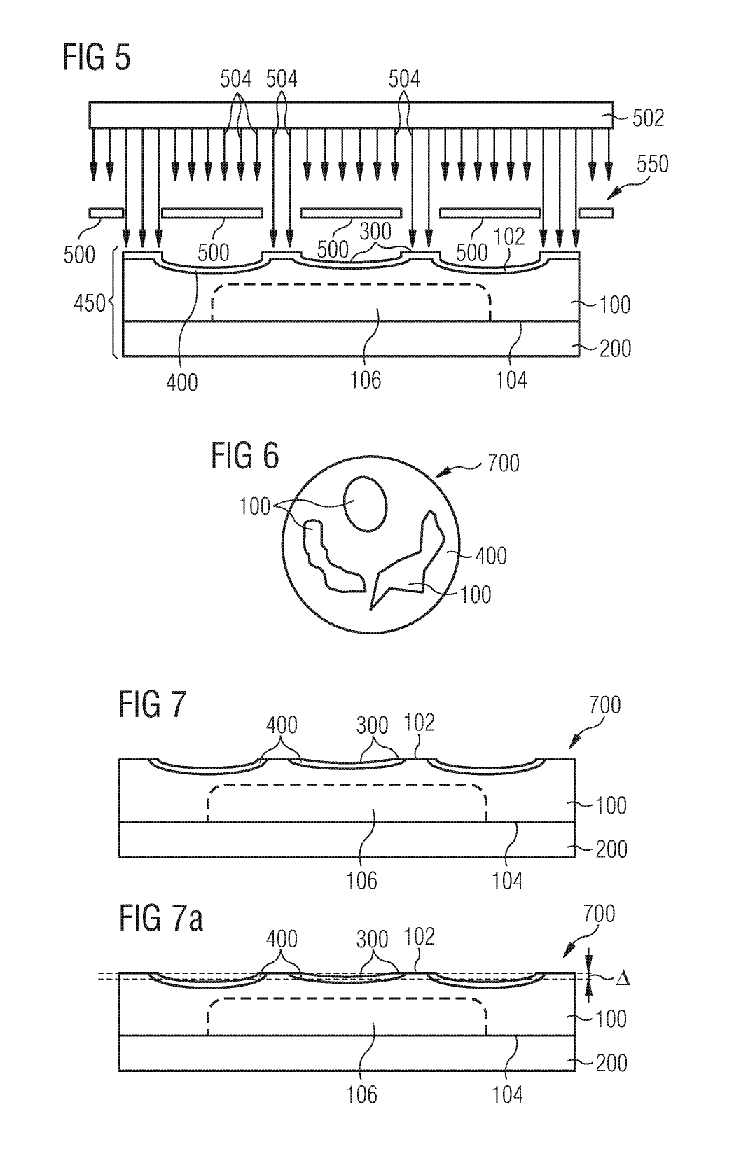

FIG. 9 shows two plan views of an electrically adjustable shadow mask 500 used in a method and an apparatus 1100 according to an exemplary embodiment. As already described above referring to FIG. 5, the mask 500 is spatially adjustable in a two-dimensional manner in terms of transmissivity for electromagnetic radiation 504 in accordance with the determined information concerning the surface topography 300 of a presently processed substrate 100. More specifically, the mask 500 may be an electrically configurable shadow mask 500 which allows to adjust or change the value of the transmissivity (for instance between fully transparent/transmissive and fully intransparent/opaque, or allowing to gradually adjust transmissivity to any desired value between zero and one, wherein zero represents an opaque and one represents a fully transparent state) for each individual pixel 900. According to FIG. 9, the mask 500 comprises a two-dimensional array of mask pixels 900 (arranged in rows and columns) each having an individually adjustable transmissivity. Depending on an electric control signal, each of the pixels 900 may be brought into a definable transmissivity state. For each pixel 900, it is further possible to change the transmissivity state later, for instance when another substrate 100 with another surface topography 300 is to be processed in terms of TTV reduction.

Thus, FIG. 9 schematically illustrates a plan view of an electrically configurable shadow mask 500. Each pixel 900 can be individually controlled in order to assume a definable transmissivity state which allows an exposure only of high topographical regions in accordance with the thickness measurement of the substrate 100. On the left-hand side of FIG. 9, a fully transmissive state of each and every pixel 900 of mask 500 is shown. On the right-hand side of FIG. 9, only two separate islands in an interior of the two-dimensional array of pixels 900 are transparent, whereas all other pixels 900 are fully opaque. The transparent pixels 900 on the right-hand side correspond to assigned surface portions of the substrate 100 to be processed which have an excessive thickness and need to be thinned for reducing the total thickness variation.

FIG. 10 shows measured thickness topologies 300 of five different substrates 100, see reference numeral 1000. The measured thickness topography 300 may be translated or converted into a corresponding thickness distribution of a layer 400 on the respective substrate 100. This can be accomplished by storing the data in accordance with reference numeral 1000 in a storage device and adjusting the individual transmissivity values or states of the individual pixels 900 of the mask 500 accordingly.

For one of these substrates which is indicated in FIG. 10 with reference numeral 100′, FIG. 10 furthermore shows two correspondingly adjusted masks 500 with different granularity according to an exemplary embodiment. The mask configuration shown on the left-hand side of FIG. 10 corresponds to a relatively coarse granularity of the mask adjustment which allows for a significant reduction of the total thickness variation with low effort and fast adaptability in terms of controlling mask 500. In contrast to this, the mask configuration shown on the right-hand side of FIG. 10 corresponds to a relatively fine granularity of the mask adjustment which allows for an even better reduction of the total thickness variation.

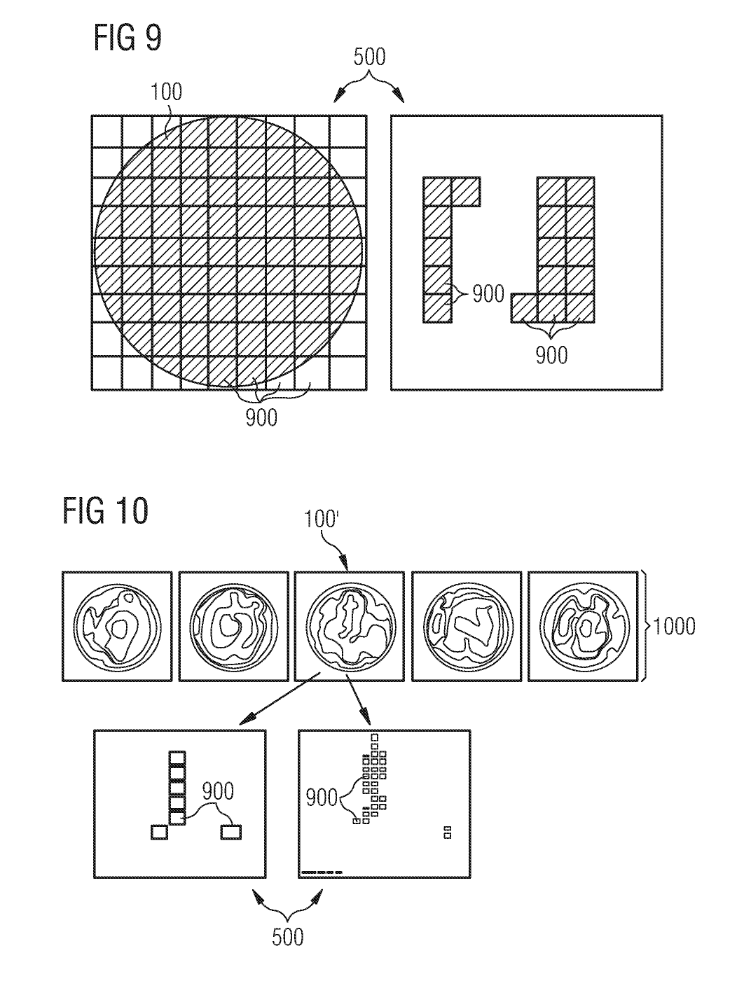

FIG. 11 illustrates an apparatus 1100 for at least partially balancing out a surface topography 300 of a substrate 100.

The apparatus 1100 comprises a determining unit 1102 configured for determining information indicative of the surface topography 300 of the substrate 100. For this purpose, an electromagnetic radiation source 1112 emits primary electromagnetic radiation 1114 onto the first main surface 102 of the substrate 100 having the surface topography 300 and being, in the shown embodiment, already covered by the conformal photoresist layer 400. Alternatively, the determination of the surface topography 300 may also be carried out on the pure substrate 100, i.e. before depositing conformal photoresist layer 400. After interaction with the substrate 100 and/or the photoresist layer 400, correspondingly reflected secondary electromagnetic radiation 1116 can be detected by an electromagnetic radiation detector 1118. Based on an analysis of the secondary electromagnetic radiation 1116, a control unit 1120 of the determining unit 1102 may determine information concerning the surface topography 300. The primary electromagnetic radiation beam 1114 may scan the entire two-dimensional surface or may detect this information only at one or several points of the two-dimensional surface of the substrate 100 covered by layer 400.

After this thickness determination procedure, the substrate 100 may be transported towards electrically controllable shadow mask 500. This transport may be accomplished by a drive mechanism such as a conveyor belt 1130.

The adjustable mask 500 defines a two-dimensional exposure pattern on the surface of the layer 400 in accordance with the thickness distribution determined by the determining unit 1102. The electrically adjustable shadow mask 500 may receive the two-dimensional thickness information via a data communication with the control unit 1120. In order to adjust transmissivity of each pixel 900 individually, a corresponding mechanical flap 1150 is assigned to each pixel 900. Each opaque flap 1150 may be flapped to a substantially horizontal orientation in which it prevents transmission of the electromagnetic radiation 504 through the respective pixel 900. It is however also possible for each opaque flap 1150 to be flapped to a substantially vertical orientation in which it allows transmission of the electromagnetic radiation 504 through the respective pixel 900.

After exposure of portions of the layer 400 in accordance with the specifically adjusted mask 500, the drive mechanism further transports substrate 100 with the patterned layer 400 thereon to a material removal unit 1104.

The material removal unit 1104 is configured for selectively removing material from one or more surface portions of the substrate 100 in accordance with the patterned layer 400 to thereby partially or fully balance out thickness variations of the substrate 100, thereby advantageously decreasing the total thickness variation by at least partly planarizing the first main surface 102, thereby reducing the surface topography 300.

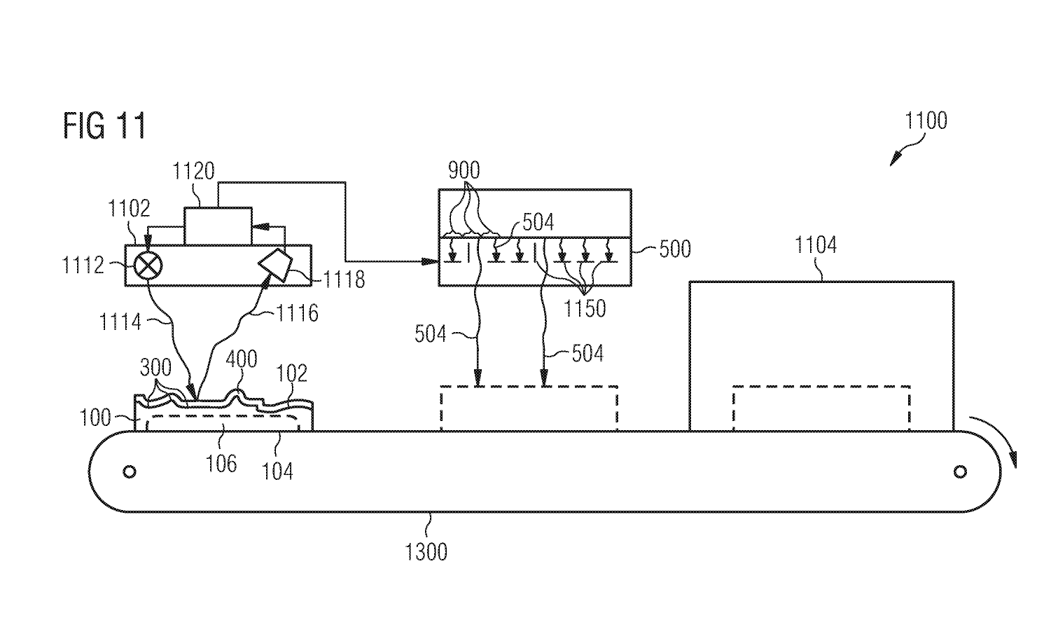

FIG. 12 illustrates a lithography device 1200 according to an exemplary embodiment.

The lithography device 1200 is configured for processing substrate 100 to reduce the total thickness variation in accordance with the above described method. For this purpose, the lithography device 1200 comprises a mask 500 configured for being controllable to provide a variable spatial transmissivity pattern for a lithography beam. The lithography device 1200 furthermore comprises a control unit 1210 configured for controlling each individual pixel 900 of the mask 500 for adjusting the spatial transmissivity pattern of the mask 500 in accordance with a previously measured surface topography 300 of the substrate 100 to be processed. The mask 500, in turn, is configured for being controllable by the control unit 1210 to provide the variable spatial transmissivity pattern based on an electric control of liquid crystal material 1202. More specifically, the liquid crystal material 1202 is located between two transparent plates 1204, 1206 having respective first and second electrodes 1208, 1210 thereon and/or therein. Under the control of the control unit 1210, an electric field may be adjusted for each pixel 900 by applying a certain voltage to an assigned pair of electrodes 1208, 1210. This will have an impact on the liquid crystal material 1202 between the respective pair of electrodes 1208, 1210 which will assume an optically transparent or an optical opaque state with regard to electromagnetic radiation 500 generated by an electromagnetic radiation source 502.

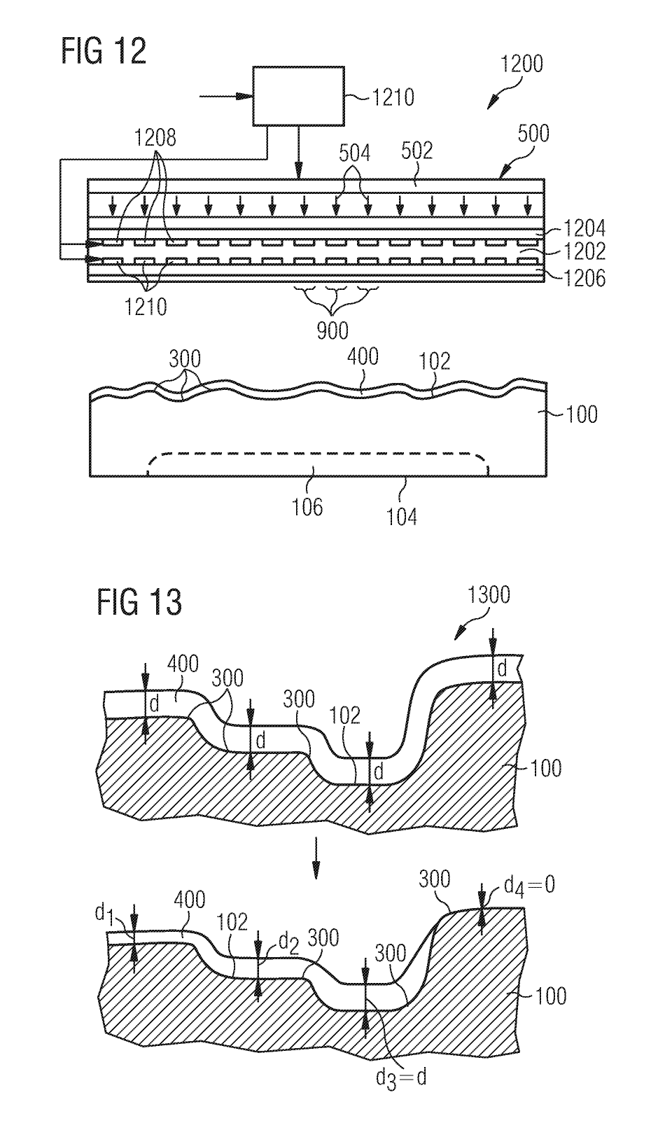

FIG. 13 illustrates a process of gradually reducing thickness of a layer 400 deposited on a substrate 100 for balancing out a surface topography in a subsequent selective material removal procedure.

The method comprises forming conformal layer 400, having the homogeneous thickness d, on substrate 100 which covers the first main surface 102. This is shown in the upper image FIG. 13, see reference numeral 1300.

As shown in the lower image of FIG. 13 (see reference numeral 1350), the method further comprises gradually reducing the thickness d of the layer 400 up to a reduced thickness which gradually differs for different surface portions in accordance with a different surface topography 300 of the substrate 100 in the different surface portions. Gradually reducing the thickness of the layer 400 for the different surface portions may be accomplished by individually adjusting a lithographic exposure time interval for each respective surface portion. As shown in FIG. 13, a surface portion with the initially highest thickness of the substrate 100 experiences a reduction of the thickness of layer 400 from d to d₄=0. Another surface portion with the initially second highest thickness of the substrate 100 experiences a reduction of the thickness of layer 400 from d to d₁<d. Yet another surface portion with the initially second smallest thickness of the substrate 100 experiences a reduction of the thickness of layer 400 from d to d₂>d₁. Still another surface portion with the initially smallest thickness of the substrate 100 experiences no reduction of the thickness of layer 400 (d=d₃).

Although not shown in FIG. 13, a thickness equilibration material removal procedure by selective etching will remove most material from the thickest substrate section with the remaining layer thickness d₄=0, followed by the second thickest substrate section with the remaining layer thickness d₁, followed, in turn, by the second thinnest substrate section with the remaining layer thickness d₂, and finally followed by the thinnest substrate section with the remaining layer thickness d=d₃. Thus, substantial planarization of substrate 100 may be achieved.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A method of thinning a substrate, the method comprising:
subjecting the substrate to a thinning process;
determining information indicative of a surface topography of the thinned substrate;
selectively removing material from at least one surface portion of the thinned substrate based on the determined information to thereby at least partially balance out thickness variations.

2. The method according to claim 1, wherein the method comprises
adjusting an adaptive variable mask, in particular an adaptive variable lithography mask, in accordance with the determined information;
carrying out the selective removal of the material using the adjusted mask.

3. The method according to claim 1, wherein the substrate is a semiconductor substrate having a first main surface with the surface topography and having a second main surface opposing the first main surface and having at least one circuit element integrated therein.

4. The method according to claim 1, wherein the substrate is mounted on a carrier, in particular prior to the thinning process.

5. The method according to claim 1, wherein the method comprises,
forming, in particular after the determining, a patterned layer on the substrate which covers the first main surface excluding at least one surface portion in which the surface topography exceeds a predefined threshold value or has a maximum;
carrying out the selective removal of material of the substrate while the patterned layer covers part of the substrate.

6. The method according to claim 1, wherein the method comprises,
forming a layer, in particular a conformal layer, on the substrate which covers the first main surface;
gradually reducing a thickness of at least part of the layer up to a reduced thickness which differs for different surface portions in accordance with a different surface topography of the substrate in the different surface portions.

7. The method according to claim 6, wherein gradually reducing the thickness of at least part of the layer for the different surface portions is accomplished by individually adjusting a lithographic exposure time interval for each respective surface portion.

8. A method of at least partially balancing out a surface topography of a substrate, the method comprising:
determining information indicative of the surface topography of the substrate;
adjusting a mask in accordance with the determined information;
selectively removing material from at least one surface portion of the substrate using the adjusted mask to thereby at least partially balance out thickness variations.

9. The method according to claim 8, wherein the method comprises, prior to be determining, subjecting the substrate to a thinning process resulting in the surface topography.

10. An apparatus for at least partially balancing out a surface topography of a substrate, the apparatus comprising:
a determining unit configured for determining information indicative of the surface topography of the substrate;
a mask being adjustable in accordance with the determined information;
a material removal unit configured for selectively removing material from at least one surface portion of the substrate using the adjusted mask to thereby at least partially balance out thickness variations.

11. The apparatus according to claim 10, wherein the mask is an electrically configurable shadow mask.

12. The apparatus according to claim 10, wherein the mask comprises a two-dimensional array of mask pixels each having an individually adjustable transmissivity.

13. A structure which comprises:
a semiconductor substrate having a first main surface with a surface topography and having a second main surface opposing the first main surface and having at least one circuit element integrated therein;
a patterned layer covering the first main surface excluding at least one surface portion in which the surface topography exceeds a predefined threshold value or has a maximum.

14. The structure according to claim 13, wherein the patterned layer is made of a material having a significantly lower removal rate, in particular etch rate, than a material of the substrate which is exposed in the at least one surface portion.

15. The structure according to claim 13, wherein a thickness of the substrate is lower than 100 μm, in particular is lower than 70 μm.

16. The structure according to claim 13, comprising a carrier on which the semiconductor substrate is mounted, wherein the second main surface is in contact with the carrier.

17. The structure according to claim 13, wherein the at least one circuit element is configured for providing a vertical current flow in thickness direction of the substrate during operation.

18. A lithography device for processing a substrate, the lithography device comprising:
a mask configured for being controllable to provide a variable spatial transmissivity pattern for a lithography beam;
a control unit configured for controlling the mask for adjusting the spatial transmissivity pattern of the mask in accordance with at least one property of the substrate to be processed.

19. The lithography device according to claim 18, wherein the mask is configured for being controllable to provide the variable spatial transmissivity pattern based on at least one of the group consisting of an electric control of liquid crystal material, and a control of a plurality of individually controllable mechanical flaps.

20. The lithography device according to claim 18, wherein the at least one property of the substrate in a surface topography of the substrate.
